(19) United States
(12) Patent Application Publication
(10) Pub. No.: US 2016/0034347 A1
(43) Pub. Date: Feb. 4, 2016

(54) MEMORY SYSTEM

(71) Applicant: Kabushiki Kaisha Toshiba, Tokyo (JP)

(72) Inventor: Kazuya Tashiro, Kawasaki Kanagawa (JP)

(21) Appl. No.: 14/614,975

(22) Filed: Feb. 5, 2015

Related U.S. Application Data
(60) Provisional application No. 62/030,292, filed on Jul. 29, 2014.

(51) Int. Cl. G06F 11/10; G06F 3/06; G11C 29/52

(52) U.S. Cl. CPC G06F 11/1068; G11C 29/52; G06F 3/0619; G06F 3/064; G06F 3/0679

(57) ABSTRACT

According to one embodiment, a memory system includes a nonvolatile memory and a controller. The nonvolatile memory includes first number of storage areas. The first number is two or more. The controller generates a plurality of second data by encoding a plurality of first data. The controller writes each piece of the second data to any one of the first number of storage areas. The controller successively repeats parallel read processing to read each piece of third data from the storage area. The parallel read processing is processing for reading, in parallel, a piece of third data from each of a second number of storage areas among the first number of storage areas. The second number is two or more. The controller determines a write destination of each piece of second data so that the second number becomes uniform for each parallel read processing.

### CROSS-REFERENCE TO RELATED APPLICATIONS

This application is based upon and claims the benefit of priority from U.S. Provisional Patent Application No. 62/030292, filed on Jul. 29, 2014; the entire contents of which are incorporated herein by reference.

### FIELD

Embodiments described herein relate generally to a memory system.

### BACKGROUND

Recently, an SSD (Solid State Drive) attracts attention as a memory system. The SSD includes multiple NAND flash memory chips (hereinafter simply referred to as memory chips).

### BRIEF DESCRIPTION OF THE DRAWINGS

FIG. 1 is a figure illustrating an example of configuration of an SSD serving as a memory system according to an embodiment;

FIG. 2 is a figure illustrating an example of configuration of each memory chip;

FIG. 3 is a figure illustrating an example of configuration of each block;

FIG. 4 is a figure illustrating an example of structure of an SRAM memory;

FIG. 5 is a figure for explaining an example of structure of a memory of a write buffer;

FIG. 6 is a figure illustrating programing location of each second cluster data;

FIG. 7 is a figure illustrating an example of structure of data of a cluster map;

FIG. 8 is a figure illustrating a cluster map after allocation;

FIG. 9 is a figure illustrating layout of each piece of second cluster data;

FIG. 10 is a flowchart for explaining operation of a processing unit during programing of first cluster data;

FIG. 11 is a figure illustrating an example of a signal transmitted to a memory chip by a NANDC during programing;

FIG. 12 is a flowchart for explaining processing in S13 further in details;

FIG. 13 is a flowchart for explaining an example of processing for setting each defective cluster to a cluster map; and

FIG. 14 is a figure illustrating an example of a signal transmitted and received between a NANDC and a memory chip during reading.

### DETAILED DESCRIPTION

In general, according to one embodiment, a memory system includes a nonvolatile memory and a controller. The nonvolatile memory includes first number of storage areas. The first number is two or more. The controller generates a plurality of second data by encoding a plurality of first data. The controller writes each piece of the second data to any one of the first number of storage areas. The controller successively repeats parallel read processing to read each piece of third data from the storage area. The third data are second data stored in the nonvolatile memory. The controller decodes each piece of the third data which are read. The parallel read processing is processing for reading, in parallel, a piece of second data from each of a second number of storage areas among the first number of storage areas. The second number is two or more. The controller determines a write destination of each piece of second data so that the second number becomes uniform for each parallel read processing.

Exemplary embodiments of a memory system will be explained below in detail with reference to the accompanying drawings. The present invention is not limited to the following embodiments.

### Embodiment

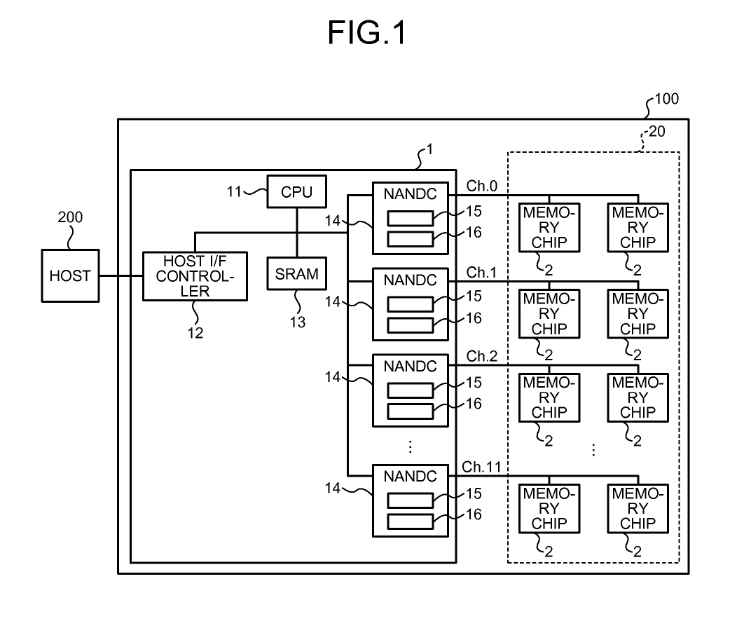

FIG. 1 is a figure illustrating an example of configuration of an SSD serving as a memory system according to an embodiment. As illustrated in FIG. 1, a SSD 100 is connected with a host 200 via a predetermined communication interface. The host 200 corresponds to, for example, a personal computer, a mobile information processing apparatus, or the like. The SSD 100 functions as an external storage apparatus for the host 200. The SSD 100 can receive an access request (read request and write request) from the host 200. The access request given by the host 200 includes a logical address designating the location of data.

The SSD 100 includes a controller 1 and multiple memory chips 2. In this case, the SSD 100 includes 24 memory chips 2. In this case, each memory chip 2 is a NAND flash memory. The 24 memory chips 2 may be collectively referred to as a NAND memory 20. It should be noted that the type of the memory chip 2 is not limited to only the NAND flash memory. For example, a NOR flash memory may be applied.

The controller 1 includes twelve channels (Ch. 0 to Ch. 11). The number of channels included in the controller 1 may be denoted as N_{channel}. More specifically, in this case, the value of N_{channel} is “12”. Each channel is connected to two memory chips 2. Each channel includes a control signal line, an I/O signal line, a CE (chip enable) signal line, and an RY/BY signal line. The I/O signal line is a signal line for transmitting and receiving data, addresses, and commands. The control signal line collectively refers to a WE (write enable) signal line, an RE (read enable) signal line, a CLE (command latch enable) signal line, an ALE (address latch enable) signal line, and a WP (write protect) signal line, and the like. The controller 1 can control the two memory chips 2 connected to any given channel independently from any memory chip 2 connected to the other channels by making use of the fact that the signal line groups of the channels are independent from each other. The two memory chips 2 connected to the same channel share the same signal line group, and therefore, the two memory chips 2 are accessed at different points in time by the controller 1.

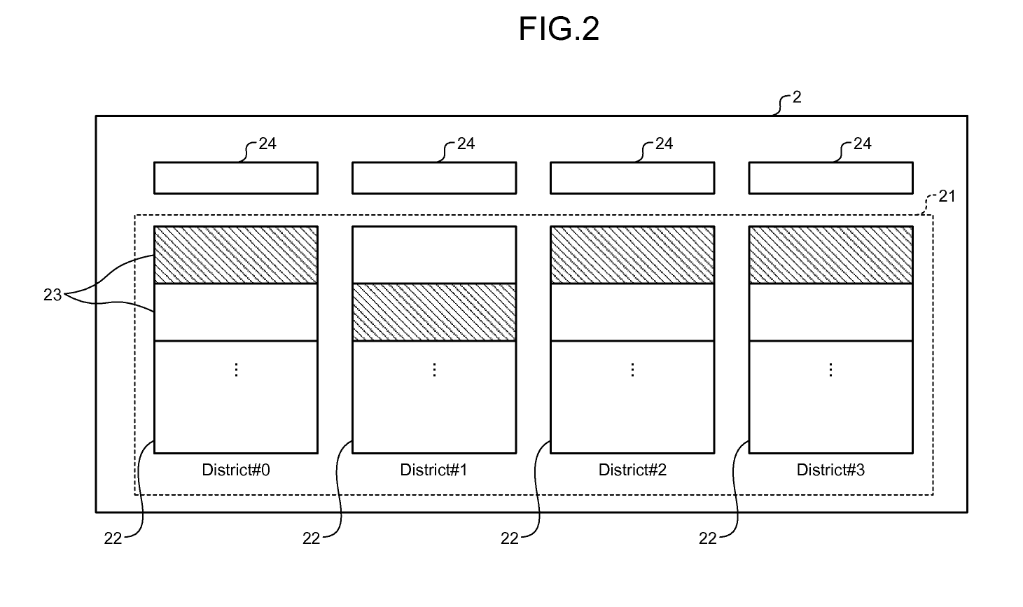

FIG. 2 is a figure illustrating an example of configuration of each memory chip 2. Each memory chip 2 has a memory cell array 21. The memory cell array 21 has multiple memory cells arranged in a matrix form. The memory cell array 21 is divided into four areas (District) 22. Each District 22 includes multiple blocks 23. Each District 22 has a peripheral circuit independent from each other (for example, a row decoder, a column decoder, a page buffer, a data cache, and the like), so that multiple Districts 22 can execute erasing/programing/reading in parallel. Each of four Districts 22 is identified by District numbers (District #0 to District #3) in each memory chip 2.

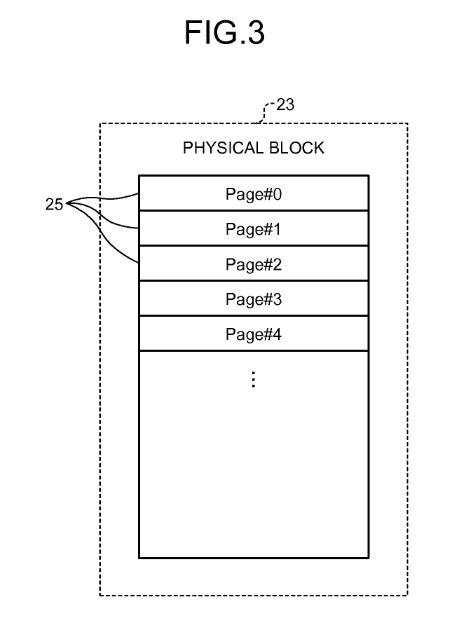

The block 23 is a unit of erasing in each District 22. FIG. 3 is a figure illustrating an example of configuration of each block 23. Each block 23 includes multiple pages 25. Each page 25 is a unit of programing and reading in each District 22. Each page 25 is identified by a page number.

In the memory chip 2, a buffer 24 is provided for each District 22. In this case, each memory chip 2 includes four Districts 22, and therefore, each memory chip 2 includes four buffers 24. The size of each buffer 24 is the same as or larger than a single page. Data sent from the controller 1 are once stored to the buffer 24, and thereafter, the data stored in the buffer 24 are programmed in the corresponding District 22. On the other hand, data read from the District 22 are once stored to the corresponding buffer 24, and thereafter, the data are sent from the buffer 24 to the controller 1. The transfer from the buffer 24 to the controller 1 is performed in order in unit of cluster data of which size is less than that of the single page 25.

It should be noted that each piece of cluster data programmed in the NAND memory 20 is encoded so as to enable error correction when it is read. Variable-length coding capable of changing the coding length according to the required correction performance is employed as the encoding method in order to cope with variation in the quality of each memory chip 2. For example, BCH coding or LDPC coding can be employed as encoding method. Cluster data that have not yet been encoded will be referred to as first cluster data. Cluster data that have been encoded will be referred to as second cluster data. It should be noted that the size of the first cluster data is fixed.

In each memory chip 2, four blocks 23 which belong to different Districts 22 are accessed at a time. The four blocks 23 accessed at a time will be referred to as a block group. Each memory chip 2 includes multiple block groups. In four blocks 23 constituting the same block group, each page 25 is subjected to programing or reading executed on totally four pages 25 which belong to different blocks 23 with the same timing and in parallel. The page numbers of the four pages 25 for which programing or reading is executed with the same timing are, for example, the same among four blocks constituting the block group.

It should be noted that each block group is set static or dynamic manner. In the example of FIG. 2, for example, four hatched blocks 23 constitute a single block group.

As described above, the controller 1 can operate the twelve memory chips 2 connected to different channels at a time, and can operate the four Districts 22 per memory chip 2 at a time. Therefore, the controller 1 can execute programing or reading on the totally 48 pages 25 at a time. The twelve block groups of which channels are different and which are accessed at a time are set in a static or dynamic manner.

The controller 1 includes a CPU 11, a host interface controller (host I/F controller) 12, an SRAM (Static Random Access Memory) 13, and twelve NAND controllers (NANDCs) 14. The CPU 11, the host I/F controller 12, the SRAM 13, and the twelve NANDCs 14 are connected with each other via a bus. The twelve NANDCs 14 are connected to different channels.

The SRAM 13 functions as a temporary storage area for various kinds of data. The memory providing the temporary storage area is not limited to an SRAM. For example, a DRAM (Dynamic Random Access Memory) can be employed as a memory providing the temporary storage area.

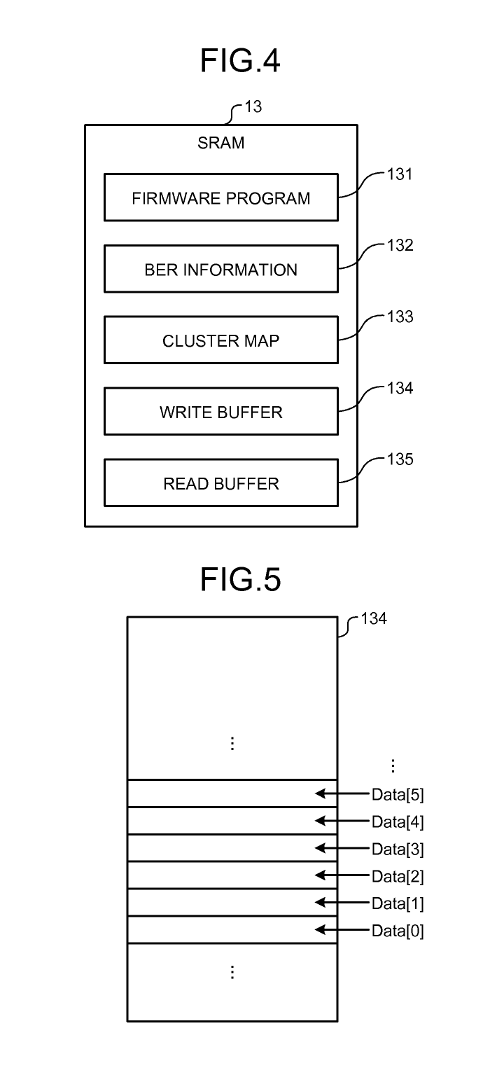

FIG. 4 is a figure illustrating an example of structure of a memory of the SRAM 13. The SRAM 13 stores a firmware program 131, BER (Bit Error Rate) information 132, and a cluster map 133. The firmware program 131 is stored to the NAND memory 20, and is read from the NAND memory 20 and stored to the SRAM 13 during booting process. The firmware program 131 stored to the SRAM 13 is executed by the CPU 11. The BER information 132 is information recording the BER of the data which are read from the NAND memory 20. The unit of recording of the BER may be any given unit. For example, the BER information 132 records the BER for each block 23. The cluster map 133 will be explained later.

The SRAM 13 includes a write buffer 134 and a read buffer 135. The write buffer 134 is a storage area in which data received from the host 200 are accumulated in units of first cluster data.

FIG. 5 is a figure for explaining an example of structure of a memory of the write buffer 134. The write buffer 134 has, for example, a structure of a ring buffer. Each Data[i] denotes first cluster data stored in the write buffer 134, and i denotes the order in which the Data[i] are buffered (hereinafter referred to as data number). The write buffer 134 buffers the first cluster data received from the host 200 in the order in which the first cluster data are received. In sequential write, multiple first cluster data of which logical addresses designated by the host 200 for each of them are continuous are buffered in the order of the logical address.

It should be noted that the sequential write means a mode for continuously write multiple first cluster data, of which logical addresses designated for each of them are continuous, to the SSD 100 in the order of logical address. In contrast, the sequential read means a mode for reading multiple first cluster data, of which logical addresses designated for each of them are continuous, from the SSD 100 in the order of the logical address.

The read buffer 135 is a storage area accumulating the first cluster data which are read from the NAND memory 20.

The CPU 11 functions as a processing unit for controlling the entire controller 1 on the basis of the firmware program 131 stored in the SRAM 13. The host I/F controller 12 executes control of the communication interface connecting between the host 200 and the SSD 100.

The host I/F controller 12 executes data transfer between the host 200 and the SRAM 13 (the write buffer 134 or the read buffer 135).

Each NANDC 14 executes the data transfer between the SRAM 13 and the memory chip 2 on the basis of the command given by the processing unit. Each NANDC 14 includes a queue 15 and an ECC unit 16. The queue 15 is a storage area for receiving a command for data transfer from the processing unit. The ECC unit 16 generates second cluster data transmitted to the NAND memory 20 by encoding the first cluster data given by the write buffer 134. The ECC unit 16 generates first cluster data transmitted to the read buffer 135 by decoding the second cluster data transmitted from the NAND memory 20. A mode indicating the strength of error correction performance is designated by the processing unit. The ECC unit 16 performs encoding and decoding in accordance with a mode designated by the CPU 11. The ECC unit 16 executes decoding, and thereafter, reports the number of error corrections to the processing unit. The processing unit updates BER information 132 on the basis of the report given by the ECC unit 16.

The processing unit calculates a mode for each block group on the basis of the BER information 132. Each ECC unit 16 performs encoding on the basis of the mode calculated for each block group, and therefore, the size of the second cluster data may be different for each block group.

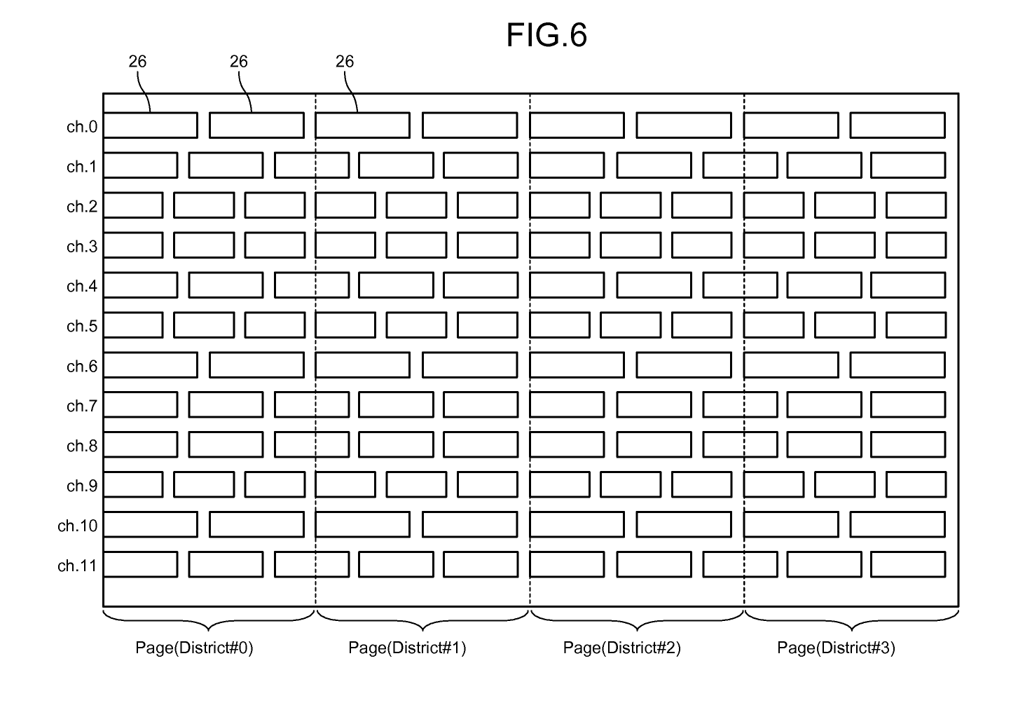

FIG. 6 is a figure illustrating a write destination (programming location) of each piece of second cluster data. FIG. 6 illustrates 48 pages accessed by the controller 1 at a time. More specifically, each line indicates a storage area for each channel. The storage area per channel is constituted by four pages of which Districts 22 are different. The four pages constituting the storage area per channel are denoted as a page group. The storage area per channel is arranged from the left side of this paper in the ascending order of the District number.

Each rectangle 26 indicates a storage location of a piece of second cluster data. The size of the second cluster data is different according of mode of encoding. In this case, the following three modes are considered to be defined: an intensity “low” which is a mode of which correction performance is the lowest; an intensity “medium” which is a mode of which correction performance is higher than the intensity “low”; and an intensity “high” which is a mode of which correction performance is higher than the intensity “medium”. In the example of FIG. 6, each ECC unit 16 of Ch.0, Ch.6, and Ch.10 executes encoding in the mode of the intensity “high”. In the explanation below, Ch.0, Ch.6, and Ch.10 will be denoted as a first group. Each ECC unit 16 of Ch.1, Ch.4, Ch.7, Ch.8, and Ch.11 executes encoding in the mode of the intensity “medium”. In the explanation below, Ch.1, Ch.4, Ch.7, Ch.8, and Ch.11 will be denoted as a second group. Each ECC unit 16 of Ch.2, Ch.3, Ch.5, and Ch.9 executes encoding in the mode of the intensity “low”. In the explanation below, Ch.2, Ch.3, Ch.5, and Ch.9 will be denoted as a third group.

The higher the intensity of the error correction performance is, the larger the size of the generated second cluster data is. Therefore, when the intensity of the error correction performance is higher, the number of second cluster data that can be programmed in the block group decreases. In the example of FIG. 6, in the case of the first group, eight second cluster data are programmed per page group. In the case of the second group, ten second cluster data are programmed per page group. In the case of the third group, twelve second cluster data are programmed per page group.

During sequential write, the processing unit executes striping when determining what programing destination in a page group of which channel each piece of the first cluster data buffered in the write buffer 134 is to be laid out. The “striping” means a method for writing the data in such a manner that multiple pieces of data of which logical addresses designated thereto are close are dispersed to as many memory chips 2 as possible in the sequential write.

More specifically, the processing unit determines the layout of the first cluster data in such a manner that multiple first cluster data of which logical addresses designated thereto are continuous are dispersed in multiple page groups of which channels are different. During the sequential read, the controller 1 can obtain multiple first cluster data, of which logical addresses designated thereto are continuous, from multiple page groups of which channels are different at the same point in time, and this improves the read performance. A group constituted by multiple first cluster data obtained at the same point in time from multiple different channels in the sequential read will be denoted as a cluster group. The processing for reading multiple second cluster data which belong to the same cluster group at the same point in time in parallel will be denoted as a parallel read processing. Each cluster group is identified by a cluster group number.

The processing unit generates a cluster map 133 as temporary data for determining the layout of the first cluster data. The cluster map 133 is stored to the SRAM 13.

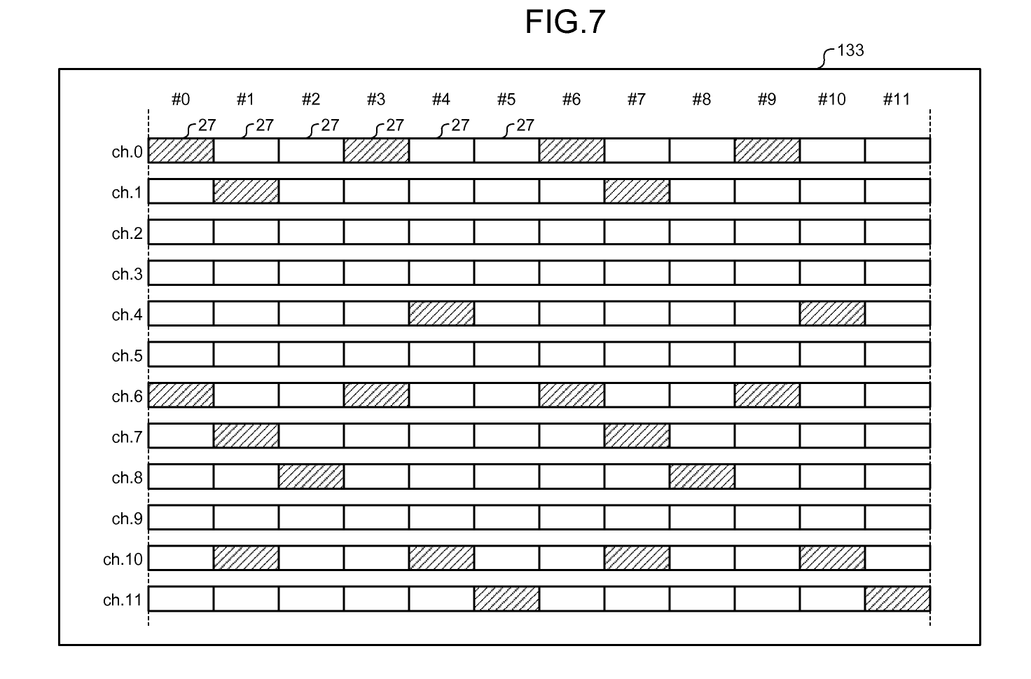

FIG. 7 is a figure illustrating an example of structure of data of the cluster map 133. In this example, the cluster map 133 has a data structure in a table configuration including multiple cells 27 having each channel as a row attribute and having each cluster group as a column attribute. Cluster group number is allocated to cluster groups so that the cluster group numbers are in the ascending order in which the data are read during sequential read. The number of cluster groups is equal to “12” which is the maximum number that can be written to a single page group during encoding in the mode of the intensity “low”.

The order in which multiple first cluster data allocated to multiple cells 27 of which row attributes are the same are arranged correspond to the order in which the first cluster data are laid out from the center of the page group. After the first cluster data are encoded, the first cluster data are laid out in the order according to the cluster group numbers allocated by the cluster map 133 and in the order from the head of each page group.

The processing unit allocates the first cluster data to each of the cells 27 possessed by the cluster map 133. The processing unit allocates, one by one, multiple first cluster data of which logical addresses respectively designated to all the cells 27 of which row attributes are cluster group #i are continuous, and thereafter, allocates first cluster data subsequent to the first cluster data allocated lastly to one of the multiple cells 27 of which row attribute is cluster group #i+1. The logical address designated to the subsequent first cluster data is continuous to the logical address designated to the first cluster data allocated lastly. In this case, the processing unit executes, in the order of channel number, the allocation to the cells 27 which belong to the same cluster group. The processing unit may execute, in the order different from the order of the channel number, the allocation to the cells 27 which belong to the same cluster group.

Hatched cells 27 are unallocatable. The unallocatable cell 27 will be referred to as a defective cluster for the sake of convenience. The number of defective clusters per page group is equal to a difference from the maximum number that can be written to a single page group in a case where the data are programmed in the mode of the intensity “low”. More specifically, in the page group where the encoding is executed in the mode of the intensity “medium”, ten pieces of second cluster data can be programmed, and therefore, there are two defective clusters. In the page group where the encoding is executed in the mode of the intensity “high”, eight pieces of second cluster data can be programmed, and therefore, there are four defective clusters. The processing unit sets each defective cluster in the cluster map 133 so that the number of defective clusters per cluster group becomes uniform among all the cluster groups. In this case, “uniform” means that the fluctuation range of the number of channels operating in parallel is less than that of a comparative example explained later.

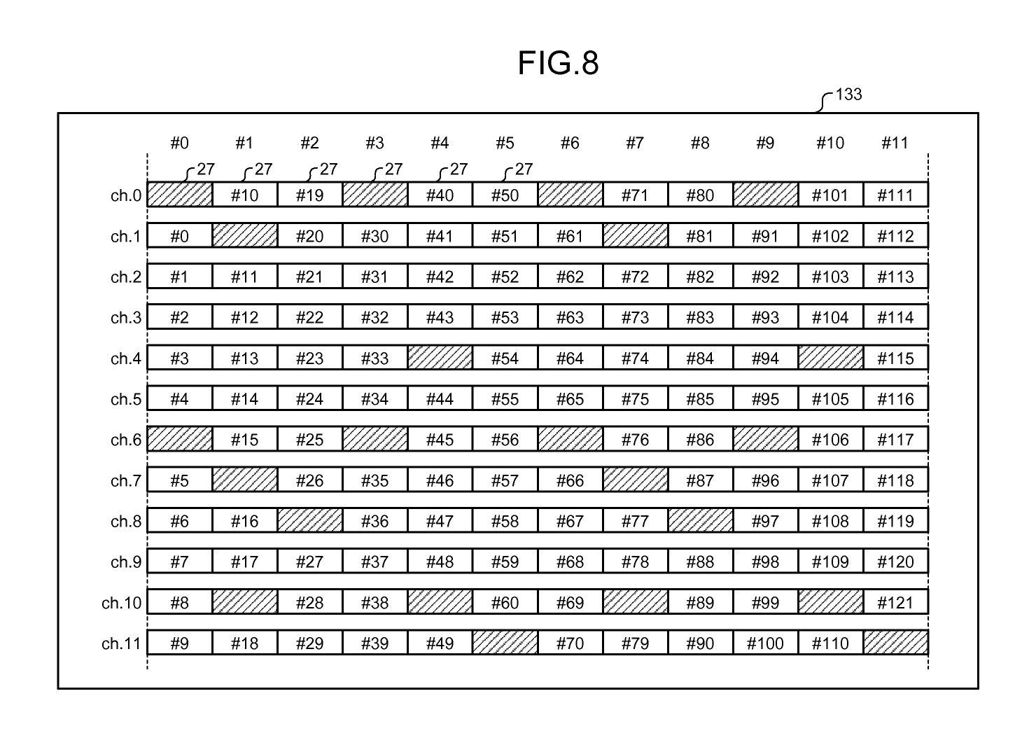

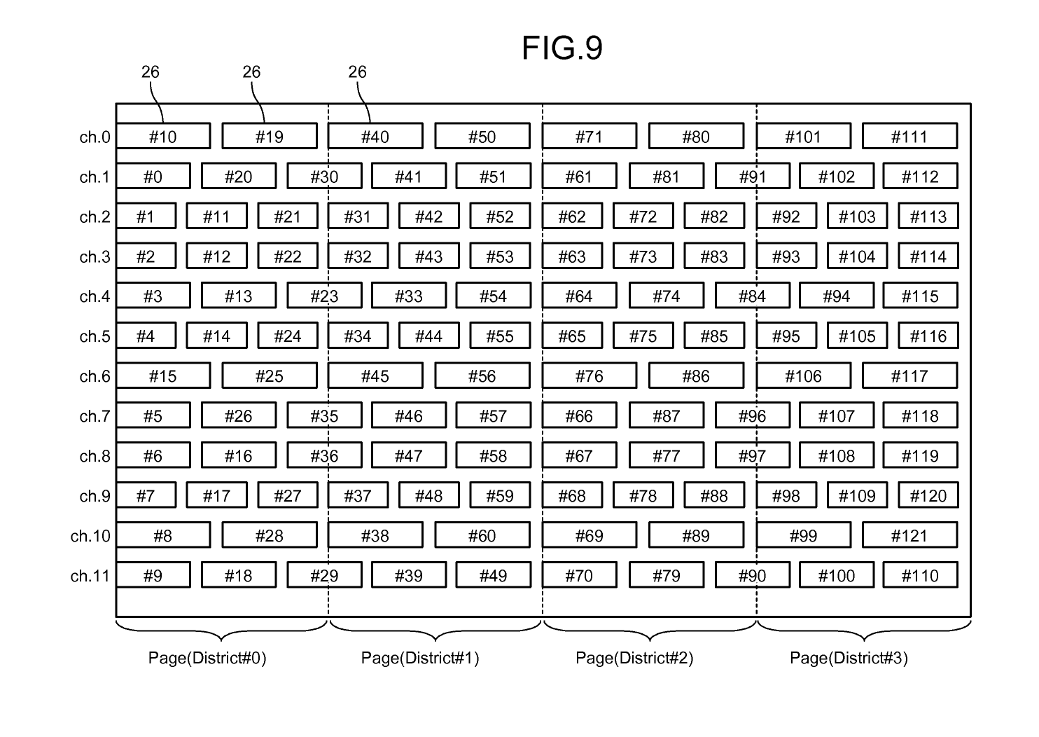

FIG. 8 is a figure illustrating a cluster map 133 after allocation. FIG. 9 is a figure illustrating the layout of the second cluster data corresponds to the cluster map 133 as illustrated in FIG. 8. In FIG. 8, a data number is indicated with each cell 27. In FIG. 9, each rectangle 26 is attached with a data number of the second cluster data thereof. The data numbers of the second cluster data respectively correspond to the data numbers of the first cluster data before encoding.

For example, according to the cluster map 133 of FIG. 8, the first cluster data are allocated to the cells 27 which belong to ch.0 in the ascending order of the cluster group number, which are in the order of Data[10], Data[19], Data[40], Data[50], Data[71], Data[80], Data[101], Data[111]. Therefore, as illustrated in FIG. 9, in the page group of ch.0, the second cluster data are laid out in the order of Data[10], Data[19], Data[40], Data[50], Data[71], Data[80], Data[101], Data[111] which are arranged from the first one in order.

According to the layout of FIG. 9, during sequential read, Data[0] to Data[9] are transferred from the NAND memory 20 to the controller 1 as a cluster group #0 at a time. At this occasion, totally ten channels, which are ch.1 to ch.5, and ch.7 to ch.11, operate in parallel. Subsequently, Data[10] to Data[18] are transferred from the NAND memory 20 to the controller 1 at a time. At this occasion, totally nine channels, which are ch.0, ch.2 to ch.6, ch.8, ch.9, and ch.11, operate in parallel. As described above, when cluster groups are transferred totally twelve times, the number of channels operating in parallel changes in the order of “10”, “9”, “11”, “10”, “10”, “11”, “10”, “9”, “11”, “10”, “10”, “11”, and the fluctuation range thereof is “2”.

For example, a case where each defective cluster is configured to be continuous from a cell 27 of which cluster group number is large will be considered (hereinafter referred to as a comparative example). According to the comparative example, the number of channels operating in parallel change in the order of “12”, “12”, “12”, “12”, “12”, “12”, “12”, “12”, “9”, “9”, “4”, “4”, and the fluctuation range thereof is “8”. Therefore, according to the present embodiment, the fluctuation range of the number of channels operating in parallel is smaller as compared with the comparative example.

Subsequently, operation of the SSD 100 according to the embodiment will be explained.

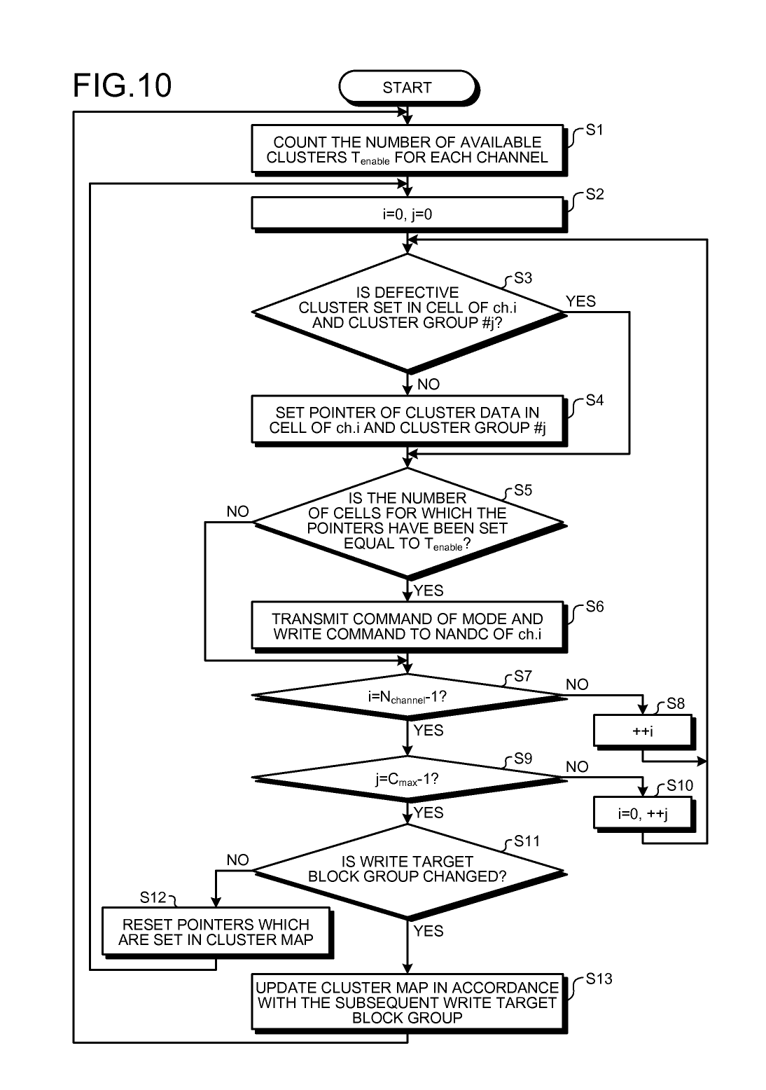

FIG. 10 is a flowchart for explaining operation of a processing unit according to programing of the first cluster data. First, the processing unit refers to the cluster map 133 and calculates the number of available clusters T_{enable} for each channel (S1). T_{enable} can be obtained by subtracting the number of defective clusters from the maximum number Cmax that can be written to a single page group in a case where the data are programmed in the mode of the intensity “low”. In this case, Cmax is 12. The processing unit initializes a parameter i and a parameter j to “0” (S2). The parameter i and the parameter j are used in the subsequent processing.

Subsequently, the processing unit determines whether a defective cluster is set in a cell 27 of which row attribute is ch.i and column attribute is a cluster group #j (S3). When the defective cluster is not set in the cell 27 (S3, No), the processing unit sets a pointer in the cell 27 (S4). The pointer that is set in the processing of S4 indicates the location where the first cluster data are stored in the write buffer 134. For example, the processing of S4 is executed at the point in time when new first cluster data are stored to the write buffer 134. The pointer which is set in the processing of S4 indicates the location where the new first cluster data are stored. When a defective cluster is set in a cell 27 of which row attribute is ch.i and column attribute is cluster group #j (S3, Yes), the processing unit skips the processing of S4.

Subsequently, the processing unit determines whether the number of cells 27 for which the pointers have been set among the group of the cells 27 of which row attributes are ch.i is equal to T_{enable} or not (S5). When the number of cells 27 for which the pointers have been set is equal to T_{enable} (S5, Yes), the processing unit transmits a command of a mode and a write command to the NANDC 14 of ch.i (S6).

When the NANDC 14 of ch.i receives the command of the mode and the write command in the queue 15, the NANDC 14 of ch.i refers to the group of the cells 27 having the row attribute ch.i of the cluster map 133, and identifies the storage location of the first cluster data and the layout order in the write buffer 134. The NANDC 14 of ch.i reads the first cluster data from the storage location identified. In the NANDC 14 of ch.i, the ECC unit 16 encodes the each piece of first cluster data having been read in the mode commanded in the processing of S7, thus generating multiple second cluster data. The NANDC 14 of ch.i arrange the generated second cluster data in the order of the layout identified, thus generating four pieces of data (page data) for each District 22. The NANDC 14 of ch.i transmits the four generated page data to the program-target memory chip 2, and causes the memory chip 2 to execute programing.

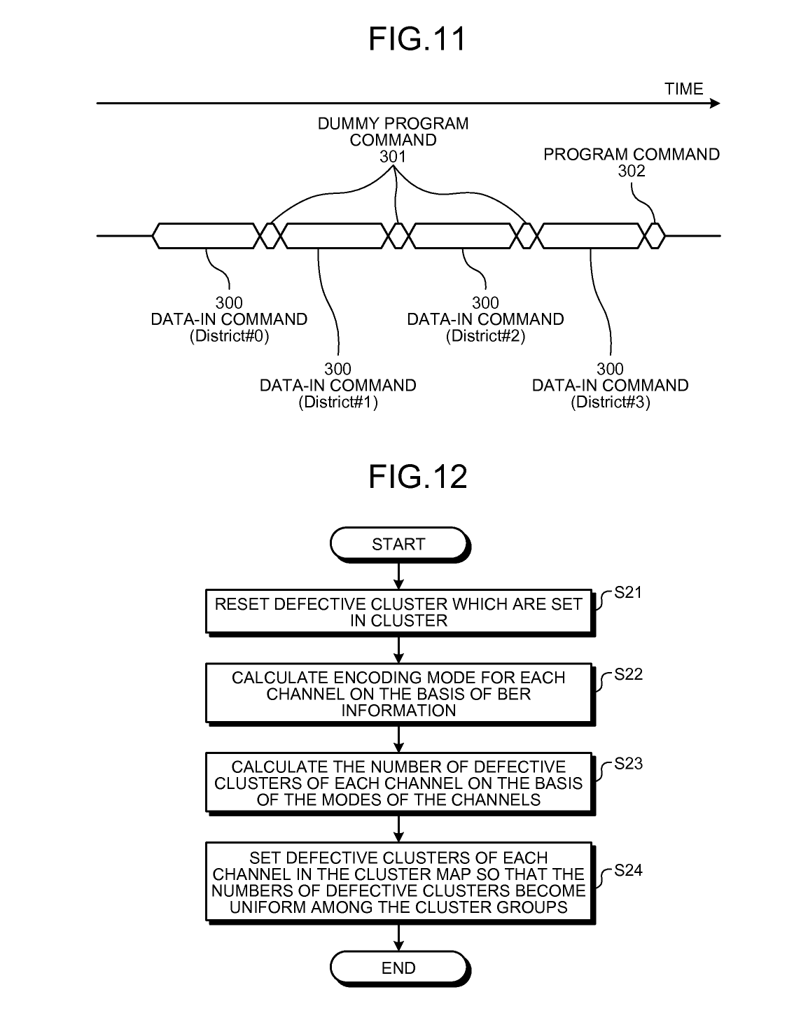

FIG. 11 is a figure illustrating an example of signal which the NANDC 14 transmits to the memory chip 2 during programing. The NANDC 14 transmits a data-in command 300 to each District 22 in order. Each data-in command 300 includes a physical address for physically identifying a destination page and page data. A correspondence between a physical address and a logical address is managed by the processing unit, and the physical address recorded to each data-in command 300 is, notified by, for example, the processing unit. The NANDC 14 transmits a dummy program command 301 between any given two data-in commands 300 successively transmitted. After the NANDC 14 finishes transmission of the data-in commands 300 for all the Districts 22, the NANDC 14 transmits a program command 302.

In the memory chip 2, the page data included in the data-in command 300 are respectively stored to the buffers 24 of corresponding Districts 22. When the memory chip 2 receives the program command 302, the memory chip 2 respectively programs the page data stored in the four buffers 24 to the corresponding Districts 22 at a time.

After the processing of S6, or, in a case where the number of cells 27 for which the pointers have been set among the group of the cells 27 of which row attributes are ch.i is different from T_{enable} (S5, No), the processing unit determines whether the value of the parameter i matches N_{channel}-1 (S7) . In this case, the value of N_{channel}-1 is “11”. When the value of the parameter i does not match N_{channel}-1 (S7, No), the processing unit increases the value of the parameter i by “1” (S8). After the processing of S8, the processing of S3 is executed.

When the value of the parameter i matches N_{channel}-1 (S7, Yes), the processing unit determines whether the value of the parameter j matches Cₘₐₓ-1 or not (S9). In this case, the value of Cₘₐₓ-1 is “11”. When the value of the parameter j does not match Cₘₐₓ-1 (S9, No), the processing unit increases the value of the parameter j by “1”, and changes the value of the parameter i to “0” (S10). After the processing of S10, the processing of S3 is executed.

When the value of the parameter j matches Cₘₐₓ-1 (S9, Yes), the processing unit determines whether the write target block group is changed or not (S11). For example, when programming has been finished on the final page group in the write target block groups, the processing unit determines Yes in the processing of S11.

When the write target block group is not changed (S11, No), the processing unit resets each pointer which is set in the cluster map 133 (S12), the processing of S2 is executed again. When the write target block group is changed (S11, Yes), the processing unit updates the cluster map 133 in accordance with the subsequent write target block group (S13), the processing of S1 is executed again.

FIG. 12 is a flowchart for explaining the processing of S13 further in details. First, the processing unit resets all the pointers and all the defective cluster which are set in the cluster map 133 (S21). The processing unit calculates the encoding mode for each channel on the basis of the BER information 132 (S22). For example, the processing unit calculates the mode for each channel so that the correction performance becomes higher when the average value of BER of each block constituting the subsequent write target block group is higher. Thereafter, the processing unit calculates the number of defective clusters on the basis of the modes of the channels (S23). Then, the processing unit sets the cluster map 133 so that as many defective clusters as the number calculated for the channels are such that the numbers of defective clusters become uniform among the cluster groups (S24). After the processing of S24, the processing of S13 is finished.

It should be noted that the method for setting each defective cluster to the cluster map 133 may be any method as long as it can reduce variation in the numbers of defective clusters among the cluster groups.

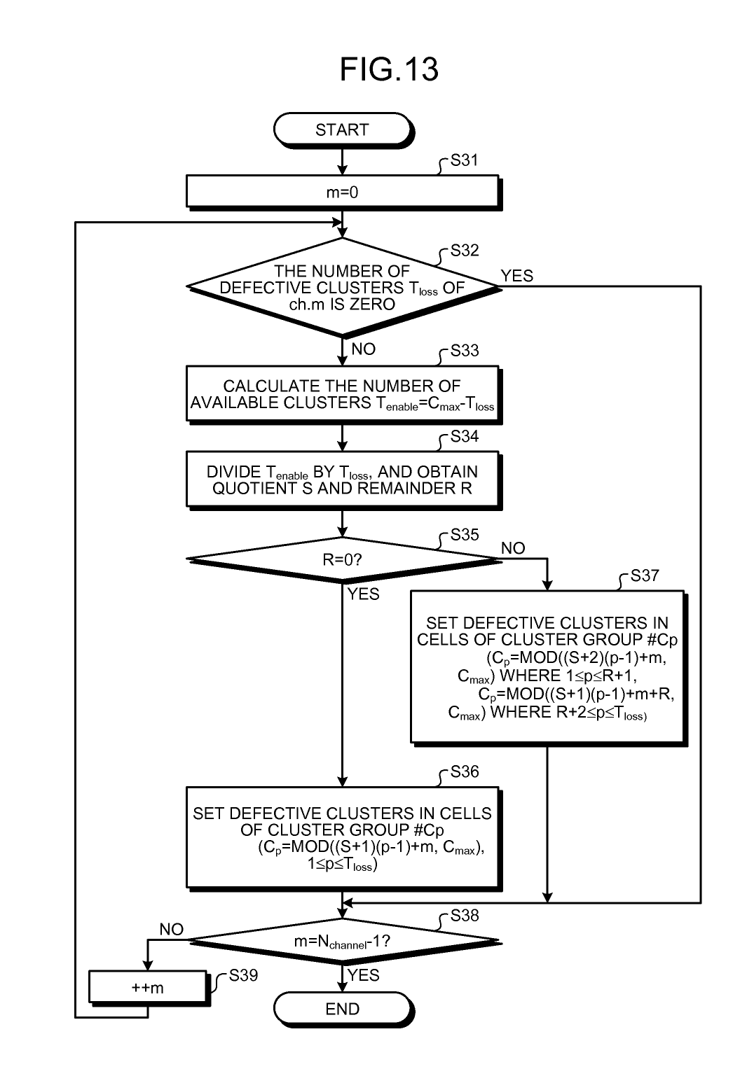

FIG. 13 is a flowchart for explaining an example of processing for setting each defective cluster in the cluster map 133. First, the processing unit initializes a parameter m to “0” (S31). The parameter m is used in subsequent processing.

Subsequently, the processing unit determines whether the number of defective clusters Tₗₒₛₛ of ch.m is zero or not (S32). When the number of defective clusters Tₗₒₛₛ of ch.m is not zero (S32, No), the processing unit calculates the number of available clusters T_{enable} for ch.m (S33). The method for calculating T_{enable} is the same as the method for calculating the processing of S1.

Subsequently, the processing unit divides T_{enable} by Tₗₒₛₛ, and obtains a quotient S and a remainder R (S34). Then, the processing unit determines whether the value of R is zero or not (S35). When the value of R is zero (S35, Yes), the processing unit identifies Tₗₒₛₛ cells 27 on the basis of calculation of an expression (1) below, and sets the defective clusters in each of the Tₗₒₛₛ cells 27 identified (S36).

In the processing of S36, the processing unit identifies, as a setting target of a defective cluster, a cell 27 having a row attribute of ch.m and having a column attribute of cluster group #Cp. Cp is derived from the calculation of an expression (1) below. Here, p is an integer satisfying 1≦p≦Tₗₒₛₛ.

Cₚ=MOD((S+1)(p−1)+m, Cₘₐₓ) (1)

When the value of R is not zero (S35, No), the processing unit identifies Tₗₒₛₛ cells 27 on the basis of calculation of an expression (2) below, and respectively sets the defective clusters to the Tₗₒₛₛ cells 27 identified (S37).

In the processing of S37, the processing unit identifies, as a setting target of a defective cluster, a cell 27 having a row attribute of ch.m and having a column attribute of cluster group #Cp. Cp is derived from the calculation of an expression (2) and an expression (3) below. Here, p is an integer satisfying 1≦p≦Tₗₒₛₛ. Where p satisfies the relationship of 1≦p≦R+1, the expression (2) is used. Where p satisfies the relationship of R+2≦p≦Tₗₒₛₛ, the expression (3) is used.

Cₚ=MOD((S+2)(p−1)+m, Cₘₐₓ) (2)

Cₚ=MOD((S+1)(p−1)+m+R, Cₘₐₓ) (3)

After the processing of S36, the processing unit determines whether the value of the parameter m matches N_{channel}-1 or not (S38) after the processing of S37 or the number of defective clusters Tₗₒₛₛ of ch.m is zero (S32, Yes). When the value of the parameter m does not match N_{channel}-1 (S38, No), the processing unit increases the value of the parameter m by “1” (S39), the processing of S32 is executed again. When the value of the parameter m matches N_{channel}-1 (S38, Yes), the processing unit finishes the processing for setting each defective cluster to the cluster map 133.

According to this processing, each defective cluster is set as shown in the example of the cluster map 133 illustrated in FIG. 7. According to the example illustrated in FIG. 7, the number of defective clusters for each cluster group stays within the range of “1” to “3”. The processing unit may set each defective cluster so that the fluctuation range of the number of defective clusters for each cluster group, which is a difference between the maximum value and the minimum value, is less than a value which is set in advance.

For example, when the setting value of the fluctuation range is “1”, the processing unit further executes the subsequent processing in the state as illustrated in FIG. 7. More specifically, the processing unit resets a defective cluster which is set in a cell 27 having a row attribute of ch.10 and having a column attribute of cluster group #1, and instead, the processing unit sets a defective cluster in a cell 27 having a row attribute of ch.10 and a column attribute of cluster group #2. Then, the processing unit resets a defective cluster which is set in a cell 27 having a row attribute of ch.7 and having a column attribute of cluster group #7, and instead, the processing unit sets a defective cluster in a cell 27 having a row attribute of ch.7 and a column attribute of cluster group #8. As a result of the above processing, the number of defective clusters for each cluster group becomes “1” or “2”, and the fluctuation range thereof is “1”.

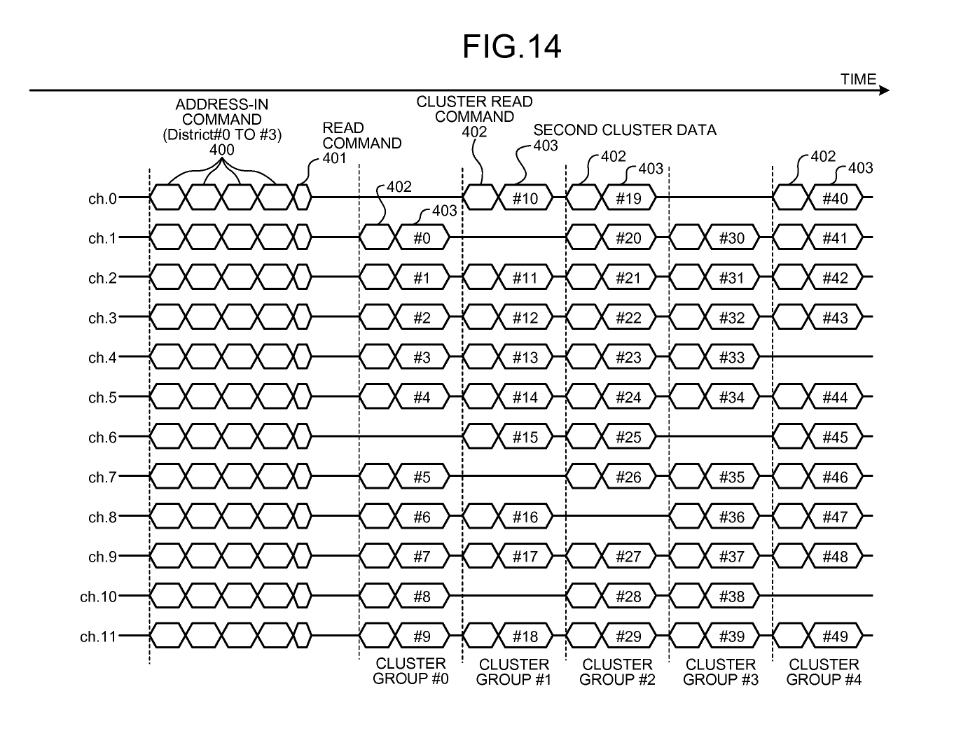

FIG. 14 is a figure illustrating an example of a signal transmitted and received between the NANDC 14 and the memory chip 2 during reading. First, each NANDC 14 continuously transmits an address-in command 400 for each District 22, and thereafter transmits a read command 401. Each address-in command 400 includes a physical address designating a page which belongs to a corresponding District 22 in the four pages 25 constituting the page group from which the data are read. The transmission of the address-in command 400 and the read command 401 is executed in parallel by each NANDC 14. When each memory chip 2 receives the read command 401, the memory chip 2 executes read process for reading page data from the memory cell array 21 in parallel in each District 22. Each piece of page data which have been read is stored to a corresponding buffer 24.

Thereafter, each NANDC 14 transmits a cluster read command 402 for each cluster group. When each memory chip 2 receives the cluster read command 402, the memory chip 2 outputs a piece of second cluster data 403. Each NANDC 14 transmits the cluster read command 402 in synchronization with another NANDC 14 for each cluster group.

In each NANDC 14, the ECC unit 16 decodes each piece of the second cluster data 403 having been received. The result of the error correction is notified from the ECC unit 16 to the processing unit. The processing unit may update the BER information 132 on the basis of the result of the error correction notified. Each piece of the first cluster data generated from decoding is accumulated in the read buffer 135. Each piece of the first cluster data accumulated in the read buffer 135 is transmitted by the host I/F controller 12 to the host 200 in the order of the logical address.

In the above explanation, multiple second cluster data which belong to the same cluster group are read in parallel with the same timing in the parallel read processing. The present embodiment can be applied to the case without any mechanism for synchronizing the read timing of multiple second cluster data which belong to the same cluster group. On the other hand, the time it takes to read each piece of the second cluster data varies in accordance with variation of the size of each piece of second cluster data or in accordance with variation in the manufacturing of the memory chip 2. Therefore, the point in time when the read of all the second cluster data which belong to the same cluster group is completed is different for each channel. For example, when each NANCC executes a read command for each second cluster data stored in the queue 15 successively in a serial manner, and when the controller 1 does not have any mechanism for synchronizing the execute timing of the read command for each cluster group between channels, the points in time when multiple second cluster data which belong to the same cluster group are read may be different from each other. Even in such case, according to the present embodiment, the fluctuation range of the number of channels operating in parallel is smaller as compared with the comparative example.

As described above, according to the embodiment, the controller 1 generates multiple second cluster data by means for encoding from multiple first cluster data, and writes the second cluster data to one of a first number of page groups, which is two or more page groups. Then, the controller 1 successively read the second cluster data from the storage areas by the parallel read processing, and decodes the second cluster data which have been read. The parallel read processing is processing for reading, in parallel, a piece of second cluster data from each of a second number of page groups which is two or more page groups. The controller 1 determines the programming location of each piece of second cluster data so that the second number becomes uniform for each parallel read processing. Therefore, the fluctuation range of the number of channels in which read is executed for each parallel read processing can be reduced as much as possible.

It should be noted that the size of the first cluster data is fixed, and the controller 1 executes encoding in accordance with variable-length coding method. The controller 1 determines the mode of encoding for each page group. The controller 1 determines the mode of encoding for each page group on the basis of the bit error rate. Therefore, the stored second cluster data are different for each page group.

The controller 1 calculates the number of writable second cluster data for each page group on the mode of encoding for each page group. Then, the controller 1 generates the cluster map 133, serving as layout information managing the programming location of the second data in units of parallel read processing, on the basis of the number of writable second cluster data. Therefore, the controller 1 can easily perform calculation as to which of the channels the second cluster data are sent to and the order in which the data are set.

The controller 1 receives multiple first cluster data in the order according to the logical address. Then, the controller 1 determines the write destination of each piece of second cluster data so that the second number of second cluster data of which logical addresses are continuous can be read by a single set of parallel read processing. Therefore, the performance in the sequential read is improved.

The NAND memory 20 has multiple memory chips 2, and the first number of page groups is provided in different memory chips 2 connected to the controller 1 via different channels. Therefore, the performance during sequential read is improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a nonvolatile memory including first number of storage areas, the first number being two or more;
a controller configured to generate a plurality of second data by encoding a plurality of first data, write each piece of the second data to any one of the first number of storage areas, successively repeat parallel read processing to read each piece of third data from the storage area, the third data being second data stored in the nonvolatile memory, and decode each piece of the third data which are read;
wherein the parallel read processing is processing for reading, in parallel, a piece of second data from each of a second number of storage areas among the first number of storage areas, the second number being two or more, and
the controller determines a write destination of each piece of second data so that the second number becomes uniform for each parallel read processing.

2. The memory system according to claim 1, wherein sizes of each piece of the first data are the same, and
the encoding is variable-length coding in which a length of code changes according to a mode of coding.

3. The memory system according to claim 2, wherein the controller determines the mode of coding for each storage area, and
the size of each piece of the second data is different for each mode.

4. The memory system according to claim 3, wherein the controller acquires a bit error rate for each storage area, and determines the mode of the coding for each storage area in accordance with the acquired bit error rate.

5. The memory system according to claim 4, wherein the controller calculates a number of writable second data for each storage area on the basis of the mode of coding for each storage area, and
the controller generates layout information managing the write destination of each piece of the second data in units of parallel read processing on the basis of the number of writable second data.

6. The memory system according to claim 1, wherein the controller receives the multiple first data in an order according to a logical address, and
determines write destination of each piece of the second data so that the second number of the third data of which logical addresses are continuous can be read in each parallel read processing.

7. The memory system according to claim 1, wherein the controller determines, in a storage area of write destination of each piece of second data, a write destination of the second data in such a manner that a fluctuation range of the second number for each parallel read processing is equal to or less than a predetermined value.

8. The memory system according to claim 1, wherein the nonvolatile memory includes a plurality of memory chips, and
the first number of storage areas is provided in different memory chips connected to the controller via different channels.

9. A memory system comprising:
a nonvolatile memory including first number of storage areas, the first number being two or more; and
a controller configured to write data to the first number of storage areas,
wherein the controller executes reading, in parallel, the data from second number of storage areas among the first number of storage areas, executes the reading plural times so that the second numbers are balanced.
